(19) United States
(12) Patent Application Publication
(10) Pub. No.: US 2009/0221133 A1
(43) Pub. Date: Sep. 3, 2009

(54) Methods of Fabricating Silicon on Insulator (SOI) Wafers

(75) Inventors: Seung-Woo Choi, Seoul (KR); Dae-Lok Bae, Seoul (KR); Jong-Wook Lee, Gyeonggi-do (KR); Yong-Won Cha, Gyeonggi-do (KR); Pil-Kyu Kang, Gyeonggi-do (KR); Jung-Ho Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd

(21) Appl. No.: 12/370,783

(22) Filed: Feb. 13, 2009

(30) Foreign Application Priority Data
Feb. 28, 2008 (KR) 2008-18392

(51) Int. Cl. H01L 21/762

(52) U.S. Cl. 438/480; 257/E21.557

(57) ABSTRACT

Methods of fabricating SOI wafers are provided including providing a donor wafer and forming a hydrogen ion implantation layer in the donor wafer. A circumference portion of one side of the donor wafer is recessed to form a height difference. The one side of the donor wafer and a handle wafer are bonded to form a bonded wafer. The bonded wafer is heat treated to separate the bonded wafer along the hydrogen ion implantation layer.

### CLAIM OF PRIORITY

This application claims priority to Korean Patent Application No. 10-2008-0018392, filed Feb. 28, 2008 in the Korean Intellectual Property Office, the disclosure of which is incorporated herein by reference as if set forth in its entirety.

### FIELD OF THE INVENTION

The present invention relates generally to semiconductor devices and, more particularly, to methods of fabricating Silicon on Insulator (SOI) wafers.

### BACKGROUND OF THE INVENTION

A SOI wafer has a structure where a buried oxide (BOX) and a single crystal silicon thin layer may be formed on a handle wafer. Semiconductor circuit patterns may be formed on the single crystal silicon thin layer. When a semiconductor device is formed using the SOI wafer, an upper region can be substantially isolated from the lower substrate. As a result, compared to a semiconductor device formed on bulk silicon, parasitic capacitance including junction capacitance and interconnection capacitance, substrate bias, and single channel effect may be decreased. Therefore, use of SOI wafers in the fabrication of semiconductor devices has been increasing, and products using SOI wafers have been continuously developed.

One method of fabricating SOI wafers includes bonding a donor wafer where a hydrogen ion implantation layer is formed and a handle wafer, and hydrogen ion implantation region is cleaved. However, when this method is used, tears and fragments can be generated at the circumference portion of a wafer. Thus, possibly causing a blistering phenomenon where the circumferences portion of the handle wafer and the donor do not match, creating fragments due to reactiveness during the cleaving period. If any of these problems occur, process reliability and yield of the semiconductor device can be affected.

### SUMMARY OF EMBODIMENTS OF THE INVENTION

Some embodiments of the present invention provide methods of fabricating SOI wafers including providing a donor wafer and forming a hydrogen ion implantation layer in the donor wafer. A circumference portion of one side of the donor wafer is recessed to form a height difference. The one side of the donor wafer and a handle wafer are bonded to form a bonded wafer. The bonded wafer is heat treated to separate the bonded wafer along the hydrogen ion implantation layer.

In further embodiments of the present invention, a height difference depth of the circumference portion of the donor wafer may be deeper than a depth where the hydrogen ion implantation layer is formed.

In still further embodiments of the present invention, recessing the circumference portion of the one side of the donor wafer to form a height difference may include forming a mask pattern on the one side of the donor wafer, wherein the mask pattern is formed on an inside of the donor wafer to expose the circumference portion of the donor wafer; recessing the circumference portion of the donor wafer using the mask pattern as an etch mask to form a height difference between the inside and the circumference portion of the donor wafer; and removing the mask pattern. In certain embodiments, the depth of the height difference of the circumference portion of the donor wafer may be deeper than a depth of the hydrogen ion implantation layer.

In some embodiments of the present invention, the circumference portion of the handle wafer which is provided to bond with the donor wafer may be etched and an inside and the circumference portion of the handle wafer may have a height difference.

In further embodiments of the present invention, the one side area of the donor wafer may be the one side area of the handle wafer which is to be bonded with the donor wafer.

In still further embodiments of the present invention, recessing may be preceded by forming a dielectric layer on a whole surface of the one side of the donor wafer. The dielectric layer may be an oxide layer. A circumference portion of the dielectric layer may be etched simultaneously when the height difference is formed at the circumference portion of the donor wafer.

In some embodiments of the present invention, heat treating may further include planarizing an upper side of the SOI layer after forming a SOI layer with a portion of the donor wafer on the handle wafer.

In further embodiments of the present invention, forming, recessing, bonding and heat treating may be repeated to form more than one layer of SOI layer.

Still further embodiments of the present invention provide methods of fabricating a SOI wafer including providing a donor wafer and forming a mask pattern at a circumference portion of the donor wafer. A hydrogen ion implantation layer is formed at a predetermined depth in an inside of the donor wafer by performing an ion implantation process using the mask pattern as an ion implantation mask. The mask pattern is removed and the donor wafer and a handle wafer are bonded. A heat treatment of the bonded wafer is performed to separate the bonded wafer along the hydrogen ion implantation layer.

In some embodiments of the present invention, an inside area of the donor wafer where the hydrogen ion implantation layer is formed and a contact area of the donor wafer and the handle wafer may be the same. A circumference of the handle wafer which is provided to bond with the donor wafer may be etched and an inside and the circumference portion of the handle wafer may have a height difference. An inside area of the donor wafer where the hydrogen ion implantation layer is formed and as an inside area of the handle wafer where the height difference is not formed may the same.

In further embodiments of the present invention, forming the mask pattern may be preceded by forming a dielectric layer on the whole surface of the donor wafer. The dielectric layer may be an oxide layer.

In still further embodiments of the present invention, more than one layer of SOI may be formed by repeating forming a mask pattern, forming a hydrogen ion implantation layer, removing, bonding and performing steps.

### BRIEF DESCRIPTION OF THE DRAWINGS

FIGS. 1A through 6 are plan and cross-sections illustrating processing steps in the fabrication of a silicon on insulator (SOI) wafers according to some embodiments of the present invention.

FIGS. 7 and 8 are cross-sections illustrating processing steps in the fabrication of SOI wafers according to some embodiments of the present invention.

FIGS. 9A through 13 are plan and cross-sections illustrating processing steps in the fabrication of SOI wafers according to some embodiments of the present invention.

### DETAILED DESCRIPTION OF EMBODIMENTS OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second region, layer or section may be termed a first region, layer or section without departing from the teachings of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the precise shape of a region of a device and are not intended to limit the scope of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

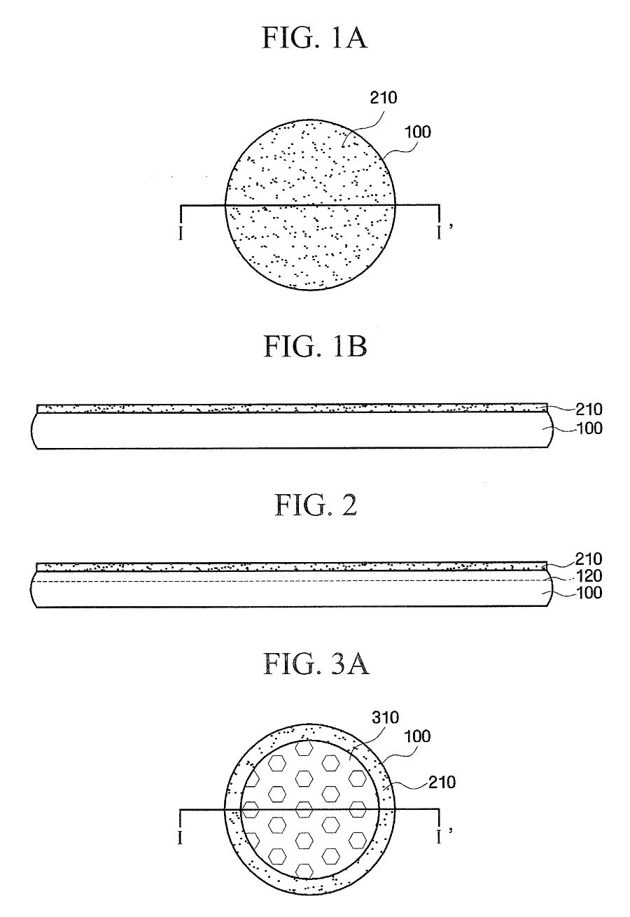

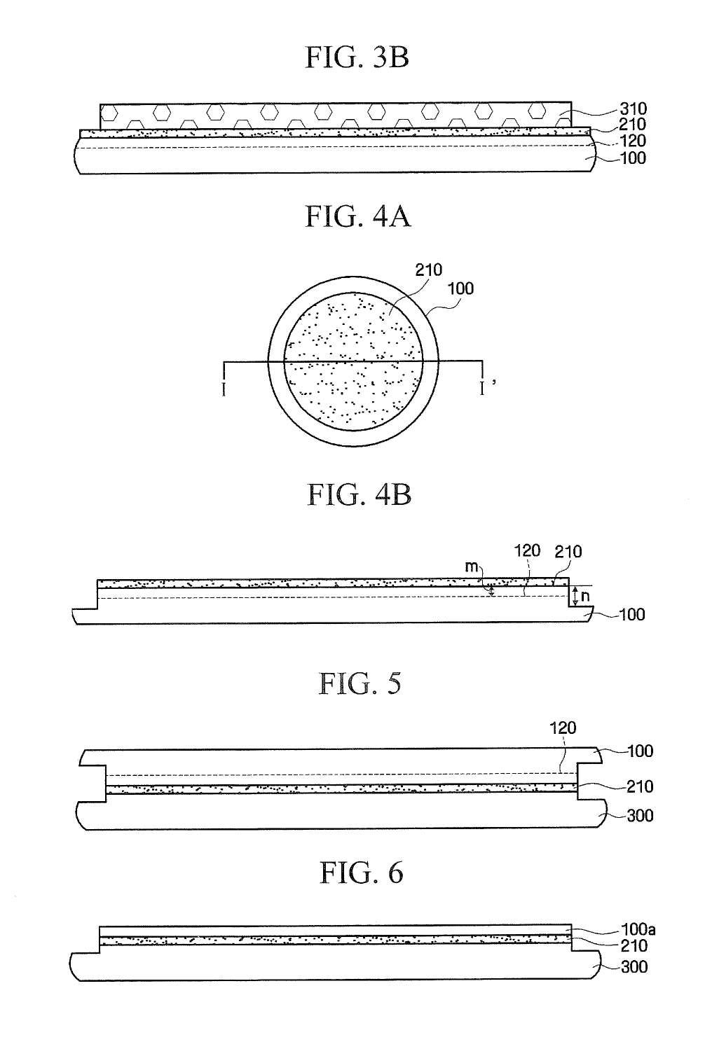

FIGS. 1A through 6 are plan and cross-section diagrams illustrating processing steps in the fabrication of SOI wafers according to some embodiments of the present invention. In particular, FIGS. 1B and 2 are cross-sections taken along a line I-I′ of FIG. 1A and sequentially illustrating processing steps in the fabrication of SOI wafers according to some embodiments of the present invention. Furthermore, FIG. 3B is a cross-section taken along a line I-I′ of FIG. 3A and FIG. 4B is a cross-section taken along a line I-I′ of FIG. 4A. Processing steps in the fabrication of SOI wafers in accordance with some embodiments of the present invention will now be discussed with reference to FIGS. 1A through 6.

Referring first to FIGS. 1A and 1B, a donor wafer 100 is provided and a dielectric layer 210 is formed on the donor wafer 100. In some embodiments, the donor wafer 100 is a wafer where circuit patterns of a semiconductor device are formed in subsequent processes, and it may be, for example, single crystal silicon. The dielectric layer 210 may be, for example, an oxide layer. The dielectric layer may be formed using, for example, a thermal oxidation process. A thickness of the dielectric layer 210 may be from about 100 Å to about 20,000 Å; however, it will be understood that the thickness of the dielectric layer 210 is not limited to this example and can be controlled depending on processes.

As illustrated in FIG. 2, a hydrogen ion implantation layer 120 is formed inside the donor wafer 100, for example, by performing an ion implantation process on one side of the donor wafer 100 where the dielectric layer 210 is formed. The hydrogen ion implantation layer 120 may be formed by implanting hydrogen ions in the donor wafer 100. The hydrogen ion implantation layer 120 is formed at a predetermined depth inside the donor wafer 100. Although the hydrogen ion implantation layer 120 is illustrated in FIG. 2 with a dotted line, the hydrogen ion implantation layer 120 is formed with a region where hydrogen ions are distributed with uniform width. The depth of the hydrogen ion implantation layer 120 can be controlled depending on the depth of the SOI layer to be formed. Since the SOI layer is formed on the hydrogen ion implantation layer 120 of the donor wafer 100, the depth of the hydrogen ion implantation layer 120 is controlled accordingly.

Referring now to FIGS. 3A and 3B, a mask pattern 310 is formed on one side of the donor wafer 100. The mask pattern 310 is formed on an inside of the donor wafer 100, and a circumference portion of the donor wafer 100 is exposed. In particular, the circumference portion of the donor wafer 100 and a portion of the dielectric layer 210 formed on the donor wafer 100 are exposed. The mask pattern 310 can be formed using, for example, a photo etch process and may be a photoresist pattern.

Referring now to FIGS. 4A and 4B, a height difference is formed on the circumference portion of the donor wafer 100 by recessing the circumference portion of the donor wafer 100 using the mask pattern 310 as etching mask. Since the circumference portion of the donor wafer 100 is recessed, the inside and the circumference portion have different heights. In these embodiments, a portion of the donor wafer and the dielectric layer 210 are etched together. The circumference portion is recessed with a depth, which is the depth of height difference n, such that the recess depth is deeper than the depth of the hydrogen ion implantation layer 120. Typical etching process can be used to etch the circumference portion of the donor wafer 100. For example, a dry etching process or wet etching process can be used. The mask pattern 310 may be removed from the top of the donor wafer 100.

Referring now to FIG. 5, one side of the donor wafer 100 and a handle wafer 300 may be bonded to form a bonded wafer One side of the donor wafer 100 where the inside and the circumference portion have a height difference and the dielectric layer 210 is formed and the handle wafer 300 are bonded. The donor wafer 100 and the handle wafer 300 are bonded by performing, for example, a hydrophilic treatment followed by hydrogen bonding. It will be understood that other methods may be used without departing from the scope of the present invention.

The handle wafer 300 serves as a support wafer to support semiconductor devices. The handle wafer 300 can have a height difference between an inner area and the circumference portion by etching a portion of the circumference portion to reduce or possibly prevent stress caused by a conductive layer. In these embodiments, due to the height difference, the area of one side of the handle wafer 300, which is bonded to the donor wafer 100, can be the same as the area of one side of the donor wafer 100 having the height difference. As illustrated in FIG. 5, the area where two wafers are bonded can be substantially the same.

Referring now to FIG. 6, the bonded wafer is separated along the hydrogen ion implantation layer 120 by performing heat treatment on the bonded wafer. As a result, an SOI wafer where the dielectric layer 210 and a SOI layer 100a are formed on the handle wafer 300 is formed. When heat treatment is performed on the bonded wafer, the donor wafer 100 is cleaved along the hydrogen ion implantation layer 120 and the bonded wafer is separated. The SOI layer 100a is formed on the dielectric layer 210. When the donor wafer 100 is cleaved, the hydrogen ion implantation layer 120 is formed on entire surface of the donor wafer 100 which is bonded to the handle wafer 300 to cause cleaving. However, since the circumference portion at each of the contact sides between the donor wafer 100 and the handle wafer 300 is removed, cleaving may not occur at the circumference portion. Therefore, fragment generation due to cleaving at the circumference portion can be reduced or possibly prevented, and process reliability and yield can be improved.

As discussed above with respect to FIGS. 1A through 6, the SOI layer 100a is formed on the handle wafer 300. By performing the processes repeatedly, more than one layer of SOI layer can be formed. Furthermore, fragments of edge due to cleaving can be inhibited or possibly prevented. Thus, process reliability and yield can be improved.

Processing steps in the fabrication of SOI wafers according some embodiments of the present invention will now be discussed with respect to FIGS. 1A through 4B, 7, and 8. As illustrated in FIGS. 1A through 4B, processing steps include providing a donor wafer 100, forming a dielectric layer 210 on the donor wafer 100, forming a hydrogen ion implantation layer 120 inside the donor wafer 100 by performing ion implantation process on one side of the donor wafer 100, forming a mask pattern 310 on one side of the donor wafer 100, and forming a height difference at a circumference portion of the donor wafer 100 by etching the circumference portion of the donor wafer 100 using the mask pattern 310 as an etching mask. Details of these processing steps are similar to those discussed above and, therefore, will not be discussed further herein.

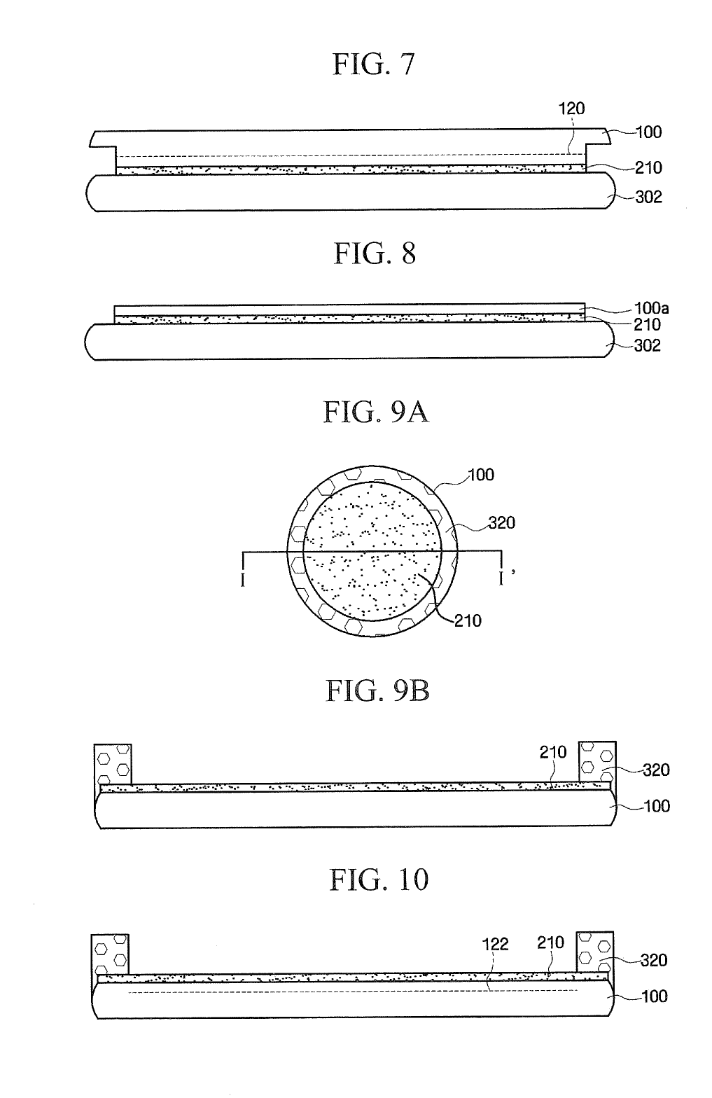

FIGS. 7 and 8 are cross-sections illustrating processing steps in the fabrication of SOI wafers according to some embodiments of the present invention. As illustrated in FIGS. 7 and 8, a bonded wafer is formed by bonding one side of the donor wafer 100 and a handle wafer 302, and a heat treatment is performed on the bonded wafer to separate the bonded wafer along the hydrogen ion implantation layer 120.

The handle wafer 302 used in these embodiments does not have a height difference at the circumference portion. Although the height difference is not formed at the circumference portion of the handle wafer 302, the circumference portion of the handle wafer 302 does not touch the donor wafer 100 since the height difference is formed due to partial recess of the circumference portion of the donor wafer 100. As a result, cleaving may not occur upon the circumference portion of the handle wafer 302. Therefore, fragments generation due to cleaving at the circumference portion of the handle wafer 302 can be inhibited or possibly prevented, and process reliability and yield can be improved.

Processing steps in the fabrication of SOI wafers in accordance with some embodiments of the present invention will now be discussed with respect to FIGS. 1A, 2, and 9A through 13. As illustrated in FIGS. 1A and 2 processing steps for providing a donor wafer 100 and forming a dielectric layer 210 on the donor wafer 100 are similar to those discussed above, accordingly, the details thereof will not be repeated herein.

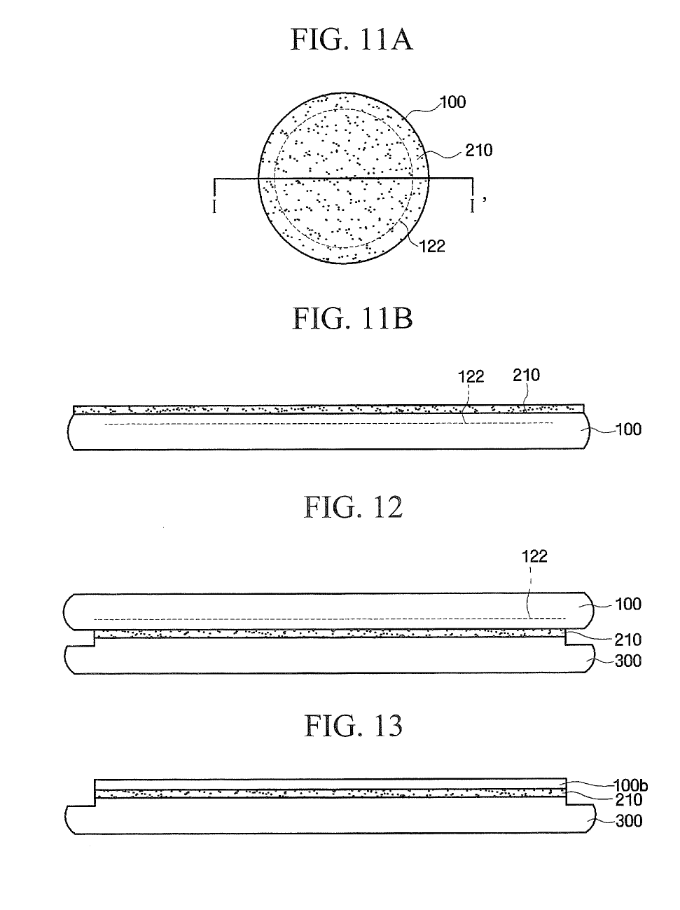

FIGS. 9A through 13 are plan and cross-section diagrams illustrating processing steps in the fabrication of SOI wafers according to some embodiment of the present invention. In particular, FIGS. 9B and 10 are cross-sections taken along a line I-I′ of FIG. 9A. Furthermore, FIG. 11B is a cross-section taken along a line I-I′ of FIG. 11A. Referring first to FIGS. 9A and 9B, a mask pattern 320 is formed on a circumference portion of the donor wafer 100. A mask pattern 320 is formed on the circumference portion of the donor wafer 100, and it is not formed on inside the donor wafer 100. As a result, the dielectric layer 210 formed on inside the donor wafer 100 is exposed. The mask pattern 320 is formed by, for example, a photo etch process and can be a photoresist pattern.

Referring now to FIG. 10, a hydrogen ion implantation layer 122 is formed at a predetermined depth inside the donor wafer 100 by performing an ion implantation process using the mask pattern 320 as ion implantation mask. The hydrogen ion implantation layer 122 is formed by implanting hydrogen ions in the donor wafer 100, and the hydrogen ion implantation layer 122 is formed at a predetermined depth inside the donor wafer 100. As illustrated in FIG. 2, although the hydrogen ion implantation layer 122 is illustrated with a dotted line, the hydrogen ion implantation layer 122 is formed with a region where hydrogen ions are distributed with uniform width. The depth of the hydrogen ion implantation layer 122 can be controlled depending on the depth of the SOI layer to be formed. Since the SOI layer is formed on the hydrogen ion implantation layer 122 of the donor wafer 100, the depth of the hydrogen ion implantation layer 122 is controlled accordingly.

Thus, according to some embodiments of the present invention, the mask pattern 320 is formed on the circumference portion of the donor wafer 100, and the hydrogen ion implantation layer 122 is formed inside of the inner area of the donor wafer 100. In other words, the hydrogen ion implantation layer 122 is not formed inside of the circumference portion of the donor wafer 100.

Referring now to FIGS. 11A and 11B, the mask pattern 320 is removed. As a result, the donor wafer 100 having the hydrogen ion implantation layer 122 formed only inside of the inner area of the donor wafer 100 is formed.

Referring now to FIG. 12, the donor wafer 100 and a handle wafer 300 are bonded. The donor wafer 100 and the handle wafer 300 are bonded by performing hydrophilic treatment followed by hydrogen combination. The handle wafer 300 serves as a support wafer to support semiconductor devices. The handle wafer 300 can have a height difference between the inner area and the circumference portion by etching portion of the circumference portion to prevent stress caused by a conductive layer. The inner area of the handle wafer 300 can have contact with a region where the hydrogen ion implantation layer 122 is formed in the donor wafer 100.

Referring now to FIG. 13, the bonded wafer is separated along the hydrogen ion implantation layer 122 by performing heat treatment on the bonded wafer. As a result, a SOI wafer where the dielectric layer 210 and a SOI layer 100b are formed on the handle wafer 300 is completed.

When a heat treatment is performed on the bonded wafer, the donor wafer 100 is cleaved along the hydrogen ion implantation layer 122 and the bonded wafer is separated. Then, the SOI layer 100b is formed on the dielectric layer 210. When the donor wafer 100 is cleaved, the hydrogen ion implantation layer 122 is formed on entire surface of the donor wafer which is bonded to the handle wafer 300 to cause cleaving. However, since the hydrogen ion implantation layer 122 is not formed at the circumference portion of the donor wafer 100, cleaving does not occur. Accordingly, cleaving does not occur at a region which does not contact with the handle wafer 300. Therefore, fragments of circumference portion due to cleaving can be inhibited or possibly prevented, and process reliability and yield can be improved.

According to some embodiments of the present invention, the SOI layer 100a is formed on the handle wafer 300, and more than one layer of SOI layer can be formed by repeating each of the processes. Furthermore, when cleaving after the handle wafer and the donor wafer are bonded, fragments due to cleaving at the circumference portion can be inhibited or possibly prevented. Therefore, process reliability and yield can be improved.

While the present invention has been particularly shown and described with reference to exemplary embodiments thereof, it will be apparent to those skilled in the art that the scope of the invention is given by the appended claims, rather than the preceding description, and all variations and equivalents which fall within the range of the claims are intended to be embraced therein. Therefore, it should be understood that the above embodiments are not limitative, but illustrative in all aspects.

What is claimed is:

1. A method of fabricating a SOI wafer, the method comprising:
providing a donor wafer;
forming a hydrogen ion implantation layer in the donor wafer;
recessing a circumference portion of one side of the donor wafer to form a height difference;
bonding the one side of the donor wafer and a handle wafer to form a bonded wafer; and
heat treating the bonded wafer to separate the bonded wafer along the hydrogen ion implantation layer.

2. The method of claim 1, wherein a height difference depth of the circumference portion of the donor wafer is deeper than a depth where the hydrogen ion implantation layer is formed.

3. The method of claim 1, wherein recessing the circumference portion of the one side of the donor wafer to form a height difference comprises:
forming a mask pattern on the one side of the donor wafer, wherein the mask pattern is formed on an inside of the donor wafer to expose the circumference portion of the donor wafer;
recessing the circumference portion of the donor wafer using the mask pattern as an etch mask to form a height difference between the inside and the circumference portion of the donor wafer; and
removing the mask pattern.

4. The method of claim 3, wherein the depth of the height difference of the circumference portion of the donor wafer is deeper than a depth of the hydrogen ion implantation layer.

5. The method of claim 1, further comprising etching the circumference portion of the handle wafer which is provided to bond with the donor wafer, where an inside and the circumference portion of the handle wafer have a height difference.

6. The method of claim 1, wherein the one side area of the donor wafer is the one side area of the handle wafer which is to be bonded with the donor wafer.

7. The method of claim 1, wherein recessing is preceded by forming a dielectric layer on a whole surface of the one side of the donor wafer.

8. The method of claim 7, wherein the dielectric layer is an oxide layer.

9. The method of claim 7, wherein a circumference portion of the dielectric layer is etched simultaneously when the height difference is formed at the circumference portion of the donor wafer.

10. The method of claim 1, wherein heat treating further comprises planarizing an upper side of the SOI layer after forming a SOI layer with a portion of the donor wafer on the handle wafer.

11. The method of claim 1, repeating forming, recessing, bonding an heat treating to form more than one layer of SOI layer.

12. A method of fabricating a SOI wafer, the method comprising:
providing a donor wafer;
forming a mask pattern at a circumference portion of the donor wafer;
forming a hydrogen ion implantation layer at a predetermined depth in an inside of the donor wafer by performing an ion implantation process using the mask pattern as an ion implantation mask;
removing the mask pattern;
bonding the donor wafer and a handle wafer; and
performing a heat treatment of the bonded wafer to separate the bonded wafer along the hydrogen ion implantation layer.

13. The method of claim 12, wherein an inside area of the donor wafer where the hydrogen ion implantation layer is formed and a contact area of the donor wafer and the handle wafer are the same.

14. The method of claim 12, further comprising etching a circumference of the handle wafer which is provided to bond with the donor wafer, wherein an inside and the circumference portion of the handle wafer have a height difference.

15. The method of claim 14, wherein an inside area of the donor wafer where the hydrogen ion implantation layer is formed and as an inside area of the handle wafer where the height difference is not formed is the same.

16. The method of claim 12, wherein forming a mask pattern is preceded by forming a dielectric layer on the whole surface of the donor wafer.

17. The method of claim 16, wherein the dielectric layer is an oxide layer.

18. The method of claim 12, further comprising forming more than one layer of SOI by repeating forming a mask pattern, forming a hydrogen ion implantation layer, removing, bonding and performing steps.
